(19) United States
(12) Patent Application Publication
(10) Pub. No.: US 2021/0167055 A1
(43) Pub. Date: Jun. 3, 2021

(54) MICRO LED DISPLAY WITH PRINTED CIRCUIT BOARD ASSEMBLY

(71) Applicant: Samsung Electronics Co., Ltd., Suwon-si (KR)

(72) Inventors: Changsun KANG, Suwon-si (KR); Mijin KIM, Suwon-si (KR); Seongjun KIM, Suwon-si (KR); Huigyeong AHN, Suwon-si (KR); Kyoree LEE, Suwon-si (KR); Sangtae HAN, Suwon-si (KR); Changjun PARK, Suwon-si (KR)

(21) Appl. No.: 17/105,890

(22) Filed: Nov. 27, 2020

(30) Foreign Application Priority Data
Nov. 29, 2019 (KR) 10-2019-0157566

(51) Int. Cl. H01L 25/18; H01L 23/498; H01L 27/12; H01L 33/62

(52) U.S. Cl. CPC H01L 25/18; H01L 23/49827; H01L 33/62; H01L 23/49822; H01L 27/1214

(57) ABSTRACT

A printed circuit board (PCB) assembly of a micro light emitting diode (LED) display is provided. The PCB assembly includes a PCB including a first face disposed in a first direction and a second face disposed in a second direction opposite to the first direction, at least one thin film transistor (TFT) circuitry constructed directly on the first face, and a plurality of pixels arranged on the first face and electrically coupled to the at least one TFT circuitry.

CROSS-REFERENCE TO RELATED APPLICATION(S)

This application is based on and claims priority under 35 U.S.C. § 119(a) of a Korean patent application number 10-2019-0157566, filed on Nov. 29, 2019, in the Korean Intellectual Property Office, the disclosure of which is incorporated by reference herein in its entirety.

### BACKGROUND

### 1. Field

The disclosure relates to a technique regarding a base substrate using a thin film transistor (TFT) for active matrix (AM) driving, and a coupling structure between the base substrate and the TFT in a micro light emitting diode (LED) display.

### 2. Description of Related Art

Driving of a regular display may be roughly classified into passive matrix (PM) driving and active matrix (AM) driving. The PM driving has a simple structure, but has a high amount of power consumption and heat generation, which makes it difficult to apply to a large-screen/high-definition display. On the contrary, the AM driving has a transistor and capacitor in unit of pixel, which results in a complex structure and high production cost, but due to low power consumption, it is possible to implement the display with a high definition and a large screen.

In general, AM-driven displays may utilize a thin film transistor (TFT) to implement a base substrate. The TFT is very small-sized transistors which are components implemented on a substrate to play a switch role of a pixel. Such switches control operations of respective pixels. Since the AM-driven displays can be implemented in very small sizes, it is possible to manufacture a high-definition thin display.

Representative examples of the TFT include a-Si/oxide-TFT/low temperature polycrystalline silicon (LTPS), or the like. Recently, in case of the high-definition display, the oxide-TFT and the LTPS are mainly used.

The above information is presented as background information only to assist with an understanding of the disclosure. No determination has been made, and no assertion is made, as to whether any of the above might be applicable as prior art with regard to the disclosure.

### SUMMARY

However, in case of the high-definition and high-performance thin film transistor (TFT), a temperature of a manufacturing process rises to about 350° C. for the oxide-TFT and about 450° C. for the low temperature polycrystalline silicon (LTPS). As a result, high heat resistant glass or Polyimide (PI) or the like capable of withstanding the temperature is inevitably used for a base substrate.

In addition, it is difficult to make a via on the base substrate in advance. The reason above is that the via bursts out when reaching a high temperature because the base substrate and the via have different thermal expansion coefficients.

For this reason, in case of a glass substrate, a display using the TFT cannot use the via and but uses a side wiring so that a signal and a power source are coupled on a rear face. In case of a PI substrate, an additional process is required in which a substrate itself is folded and turned back at an edge.

In addition, when even one pixel is defective among several pixels, a display panel may be entirely defective, which results in a throughput decrease and a cost increase.

Aspects of the disclosure are to address at least the above-mentioned problems and/or disadvantages and to provide at least the advantages described below. Accordingly, an aspect of the disclosure is to provide a micro light emitting diode (LED) display including a printed circuit board (PCB) assembly having a high-performance TFT circuitry capable of performing a TFT process directly on a PCB at a temperature of 300° C. or below.

Additional aspects will be set forth in part in the description which follows and, in part, will be apparent from the description, or may be learned by practice of the presented embodiments.

In accordance with an aspect of the disclosure, a micro LED display is provided. The micro LED display includes a PCB assembly in which components can transfer electricity between a first face and second face of a PCB by using a via and a conductive substance.

In accordance with another aspect of the disclosure, a PCB assembly is provided. The Printed Circuit Board includes a PCB including a first face disposed in a first direction and a second face disposed in a second direction opposite to the first direction, at least one TFT circuitry constructed directly on the first face, and a plurality of pixels arranged on the first face and electrically coupled to the at least one TFT circuitry.

According to various embodiments of the disclosure, a high-performance TFT can be constructed directly on one face of a PCB at a temperature of 300° C. or below.

According to various embodiments of the disclosure, an electrical coupling between a micro LED chip and a component is easily achieved without an additional coupling device.

According to various embodiments of the disclosure, an electrical coupling is easily achieved between a TFT circuitry constructed directly on one face of a PCB and a component constructed on the other face.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a partially enlarged side view illustrating a micro light emitting diode (LED) display according to an embodiment of the disclosure;

FIG. 2 is a cross-sectional view illustrating a printed circuit board (PCB) assembly according to an embodiment of the disclosure;

FIG. 3 is a plan view illustrating a PCB assembly according to an embodiment of the disclosure;

FIG. 4 illustrates a PCB assembly including an array 5×5 pixel according to an embodiment of the disclosure;

FIG. 5A is a cross-sectional view illustrating a prepared PCB according to an embodiment of the disclosure;

FIG. 5B is a cross-sectional view illustrating a state in which a thin film transistor (TFT) circuitry is directly constructed on a prepared PCB according to an embodiment of the disclosure; and

FIG. 5C is a cross-sectional view illustrating a state in which a micro LED chip is mounted after a TFT circuitry is directly constructed on a prepared PCB according to an embodiment of the disclosure.

Throughout the drawings, like reference numerals will be understood to refer to like parts, components, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

An electronic device according to various embodiments of the disclosure may include at least one of, for example, a smart phone, a tablet personal computer (PC), a mobile phone, a video phone, an e-book reader, a desktop PC, a laptop PC, a netbook computer, a workstation, a server, a personal digital assistant (PDA), a portable multimedia player (PMP), a moving pictures expert group (MPEG-1) audio layer 3 (MP3) player, a mobile medical device, a camera, and a wearable device (e.g., smart glasses, a head-mounted display (HMD), electronic clothes, an electronic bracelet, an electronic necklace, an electronic appcessory, an electronic tattoo, a smart mirror, or a smart watch).

According to some embodiments of the disclosure, the electronic device may be a home appliance. The home appliance may include, for example, at least one of a television (TV), a digital video disk (DVD) player, an audio player, a refrigerator, an air conditioner, a cleaner, an oven, a microwave oven, a washing machine, an air purifier, a set-top box, a home automation control panel, a security control panel, a TV box (e.g., Samsung HomeSync™, Apple TV™, or Google TV™), a game console (e.g., Xbox™, PlayStation™), an electronic dictionary, an electronic key, a camcorder, and an electronic picture frame.

According to other embodiments of the disclosure, the electronic device may include at least one of various medical devices (e.g., various portable medical measuring devices (e.g., a blood sugar measuring device, a heartrate measuring device, a blood pressure measuring device, a body temperature measuring device, or the like), magnetic resonance angiography (MRA), magnetic resonance imaging (MRI), computed tomography (CT), imaging equipment, ultrasonic instrument, or the like)), a navigation device, a global navigation satellite system (GNSS), an event data recorder (EDR), a flight data recorder (FDR), a car infotainment device, an electronic equipment for ship (e.g., a vessel navigation device, a gyro compass, or the like), avionics, a security device, a car head unit, an industrial or domestic robot, an automatic teller's machine (ATM) of financial institutions, point of sales (POS) of shops, and Internet of things (e.g., a light bulb, various sensors, an electric or gas meter, a sprinkler device, a fire alarm, a thermostat, a streetlamp, a toaster, a fitness equipment, a hot water tank, a heater, a boiler, or the like).

According to some embodiments of the disclosure, the electronic device may include at least one of furniture or a part of buildings/constructions, an electronic board, an electronic signature input device, a projector, and various measurement machines (e.g., water supply, electricity, gas, propagation measurement machine, or the like). In various embodiments of the disclosure, the electronic device may be one or more combinations of the aforementioned various devices. According to some embodiments of the disclosure, the electronic device may be a flexible device. Further, the electronic device according to an embodiment of the disclosure is not limited to the aforementioned devices, and may include a new electronic device depending on technical progress.

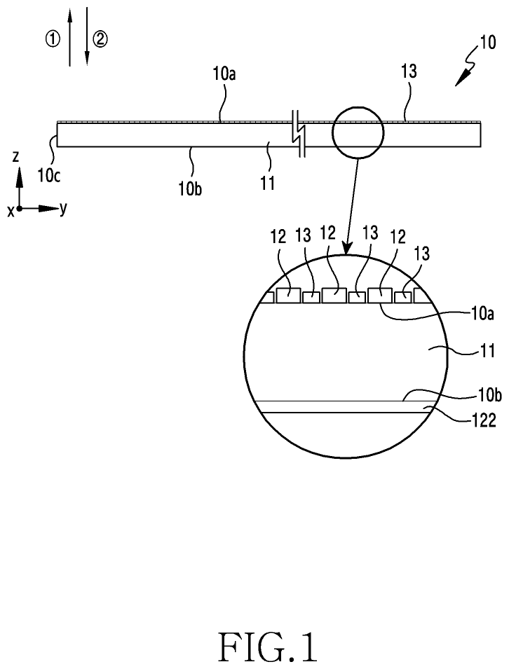

FIG. 1 is a partially enlarged side view illustrating a micro light emitting diode (LED) display according to an embodiment of the disclosure.

Referring to FIG. 1, a Cartesian coordinate system is used, in which an X-axis may be a horizontal direction of a micro LED display 10, a Y-axis may be a vertical direction of the micro LED display 10, and a Z-axis may be a thickness direction of the micro LED display 10. The illustrated micro LED display 10 may be utilized for a small-sized display, and the plurality of micro LED displays 10 may be combined to be used as a large-screen display. For example, the micro LED display 10 according to an embodiment of the disclosure is a display of an electronic device, or may be utilized for any one of a TV, a cinema movie screen, and an electric signboard.

The micro LED display 10 according to an embodiment of the disclosure may be utilized as the display of the electronic device. The micro LED display 10 according to an embodiment of the disclosure may include a printed circuit board (PCB) 11, first and second circuitries 12 and 14, and a plurality of micro LED chips 13. According to an embodiment of the disclosure, the PCB 11 may be a support plate which supports the plurality of micro LED chips 13 arranged in a plate shape. According to an embodiment of the disclosure, the PCB 11 may include a first face 10a facing a first direction \textcircled{1}, a second face 10b facing a second direction \textcircled{2} opposite to the first direction \textcircled{1}, and a third face 10c surrounding at least part of the first and second faces 10a and 10b. For example, the first face 10a may be a front face of the micro LED display 10, and the second face 10b may be four side faces of the third face 10c. According to an embodiment of the disclosure, the plurality of micro LED chips 13 may be set in unit of one pixel on the first face so that a plurality of pixels are arranged, and each of the micro LED chips 13 may implement a display area by emitting light. For example, the first face 10a may be a light emitting face.

For example, each of the plurality of micro LED chips 13 may have a size less than or equal to 100 micrometers. The size may be about tens of micrometers. Each of the plurality of micro LED chips 13 may include an R-color element, a G-color element, and a B-color element. Each of the plurality of micro LED chips 13 may implement one pixel by using the R-color element, the G-color element, and the B-color element as one set. According to an embodiment of the disclosure, the thin film transistor (TFT) circuitry 12 may be directly constructed between the plurality of micro LED chips 13 on the first face 10a of the PCB.

According to an embodiment of the disclosure, the PCB 11 may have a second circuitry 122 disposed on the second face 10b. For example, the second circuitry 122 may include a controller or a driving integrated circuit (IC).

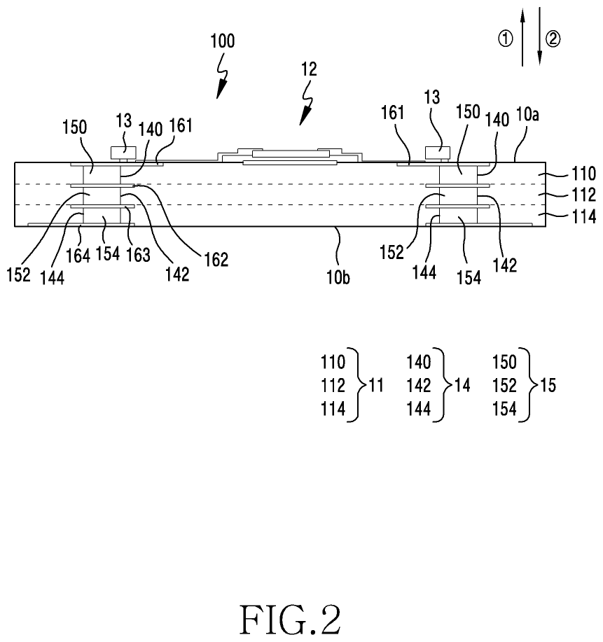

FIG. 2 is a cross-sectional view illustrating a PCB assembly according to an embodiment of the disclosure.

Referring to FIG. 2, a micro LED display according to an embodiment of the disclosure (e.g., the micro LED display 10 of FIG. 1) may include a PCB assembly 100. According to an embodiment of the disclosure, the PCB assembly 100 may include a plurality of micro LED chips 13 disposed on a first face 10a, a plurality of TFT circuitries 12, a plurality of vias 14, and a plurality of conductive substances 15.

According to an embodiment of the disclosure, each single pixel may include an R-color micro LED chip, a G-color micro LED chip, and a B-color micro LED chip. According to an embodiment of the disclosure, each of the plurality of micro LED chips 13 may be arranged on the first face 10a of a PCB 11 equidistantly along a horizontal direction and a vertical direction.

According to an embodiment of the disclosure, the plurality of micro LED chip 13 may be in contact with a first contact pad 161 constructed on the first face 10a of the PCB 11. The plurality of micro LED chip 13 may be electrically coupled to a second face 10b due to an electrical coupling structure.

According to an embodiment of the disclosure, the electrical coupling structure may include the via 14 and the conductive substance (filler) 15. According to an embodiment of the disclosure, the number of vias 14 constructed on the PCB 11 may be at least one. According to an embodiment of the disclosure, the conductive substance 15 may be constructed after the at least one via 14 is filled with a conductive material and is subjected to curing. The conductive substance 15 may be a passage through which a signal is transmitted, with a conductive structure which electrically couples a component disposed on the first face 10a to a component disposed on the second face 10b.

According to an embodiment of the disclosure, the PCB 11 may have a multi-layered structure. For example, the PCB 11 may include first to third PCBs 110, 112, and 114. According to an embodiment of the disclosure, the first PCB 110 may include the first contact pad 161, a first via 140, and a first conductive substance 150. According to an embodiment of the disclosure, the second PCB 112 may be disposed below the first PCB 110, and may include a second contact pad 162, a second via 142, and a second conductive substance 152. According to an embodiment of the disclosure, the third PCB 114 may be disposed below the second PCB 112, and may include third and fourth contact pads 163 and 164, a third via 144, and a third conductive substance 154. According to an embodiment of the disclosure, the first to third vias 140, 142, and 144 may be stacked with one another, and the first to third conductive substances 150, 152, and 154 may be stacked with one another.

According to an embodiment of the disclosure, the plurality of micro LED chips 13 may be disposed parallel to one another without overlapping with the TFT circuitry 12. According to an embodiment of the disclosure, the TFT circuitry 12 may be disposed between the plurality of micro LED chips 13. According to an embodiment of the disclosure, the plurality of micro LED chip 13 may be electrically coupled to a driving IC (not shown) coupled to the fourth contact pad 164 constructed on the second face 10b by means of the first to third conductive substances 150, 152, and 154. A control signal of a controller may be transmitted to a micro LED chip by means of the first to third conductive substances 150, 152, and 154.

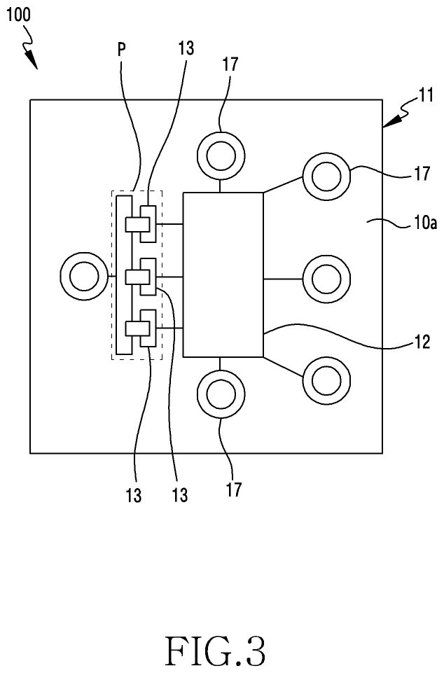

FIG. 3 is a plan view illustrating a PCB assembly according to an embodiment of the disclosure.

Referring to FIG. 3, according to an embodiment of the disclosure, each of the plurality of micro LED chips 13 disposed on a first face 10a of a PCB 11 may be disposed adjacent to a TFT circuitry 12. For example, the plurality of micro LED chip 13 with red green blue (RGB) color may construct one pixel p, and the TFT circuitry 12 may be disposed therearound. For example, one pixel p may be disposed in a one-to-one manner to the TFT circuitry 12.

According to an embodiment of the disclosure, each of the plurality of micro LED chips 13 may be electrically coupled to the TFT circuitry 12 through a wiring. According to an embodiment of the disclosure, the TFT circuitry 12 may be electrically coupled to each of contact portions 17 through a wiring. According to an embodiment of the disclosure, each of the plurality of micro LED chips 13 may be disposed not to overlap with the TFT circuitry 12 and the plurality of contact portions 17. According to an embodiment of the disclosure, one pixel p and the plurality of contact portions 17 may be disposed along a periphery of the TFT circuitry 12.

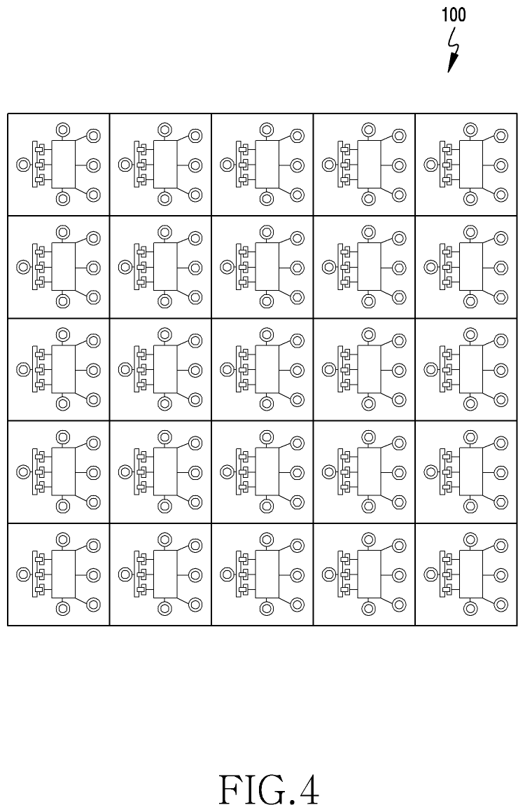

FIG. 4 illustrates a PCB assembly having an array 5×5 pixel according to an embodiment of the disclosure.

Referring to FIG. 4, TFT circuitries (e.g., TFT circuitries of FIG. 4) may be equidistantly arranged in horizontal and vertical directions between respective pixels (e.g., pixels p of FIG. 4) arranged in horizontal and vertical directions according to an embodiment of the disclosure.

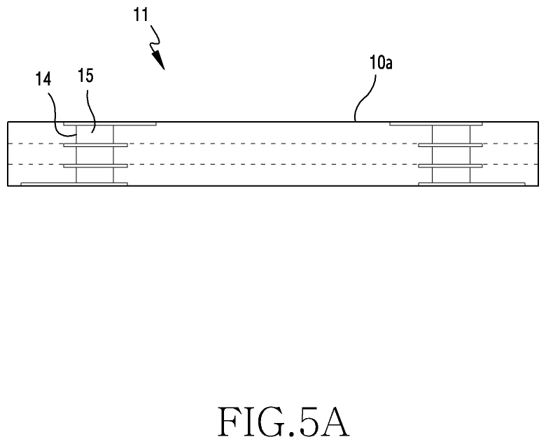

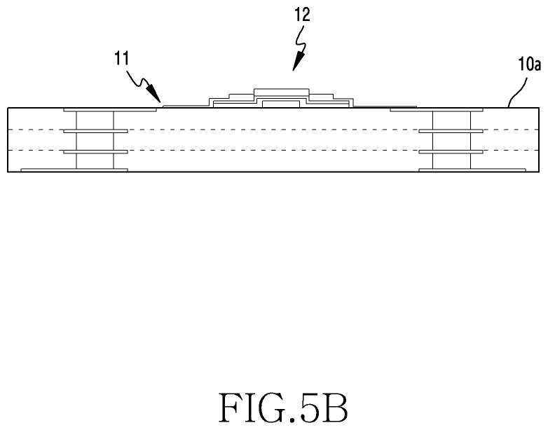

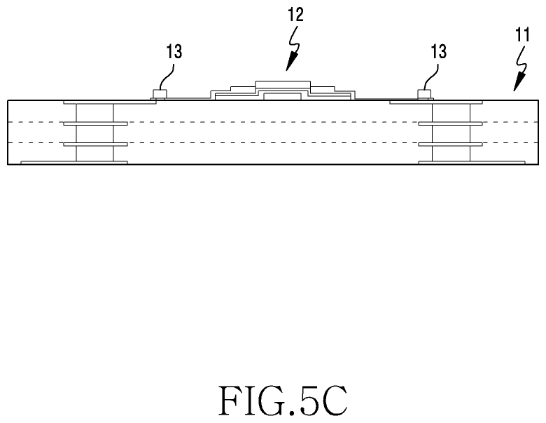

A process of manufacturing a PCB assembly according to an embodiment of the disclosure will be described with reference to FIG. 5A to FIG. 5C.

FIG. 5A is a cross-sectional view illustrating a prepared PCB according to an embodiment of the disclosure.

Referring to FIG. 5A, a PCB 11 in a bare state may be prepared by including at least one via 14 constructed thereon and a conductive substance 15 constructed in such a manner that the via 14 is filled with a conductive material, for example, copper, and is subjected to curing.

FIG. 5B is a cross-sectional view illustrating a state in which a TFT circuitry is directly constructed on a prepared PCB according to various an embodiments of the disclosure.

Referring to FIG. 5B, the prepared PCB 11 in the bare state may have a TFT circuitry 12 directly constructed on a first face 10a through a low-temperature TFT process based on a semiconductor standard process. For example, the low temperature may be less than or equal to approximately 300° C. According to an embodiment of the disclosure, a process temperature at which the TFT circuitry 12 is constructed shall be a temperature at which there is no thermal deformation or thermal damage to the PCB 11. For example, a TFT which utilizes a carbon nano tube (CNT) may be an alternative for the TFT process. According to an embodiment of the disclosure, in a process of constructing the TFT circuitry 12, a source electrode and a drain electrode may be constructed on the first face 10a of the PCB, and an organic semiconductor layer, a gate insulating layer, and a gate electrode may be constructed sequentially on the source electrode and the drain electrode.

According to an embodiment of the disclosure, when the TFT circuitry 12 is constructed on the first face 10a of the PCB, the TFT circuitry 12 may be implemented step by step by using a metal thin film process, and then may be complete by electrically coupling wirings and respective I/Os of the TFT circuitry 12.

FIG. 5C is a cross-sectional view illustrating a state in which a micro LED chip is mounted after a TFT circuitry is directly constructed on a prepared PCB according to various an embodiments of the disclosure.

Referring to FIG. 5C, plurality of micro LED chips 13 may be mounted between the TFT circuitries 12 constructed in the PCB assembly manufactured with such a process. A state where the plurality of micro LED chips 13 are mounted is illustrated in FIG. 3, FIG. 4, and FIG. 5C. According to an embodiment of the disclosure, the plurality of micro LED chips 3 may be moved by a carrier and then may be transferred to the first face 10a of the PCB in a down state of a contact pad. Although not shown in the figure, the plurality of micro LED chips 13 may be disposed on the TFT circuitry 12.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. A micro light emitting diode (LED) display comprising:
a printed circuit board (PCB) comprising a first face disposed in a first direction and a second face disposed in a second direction opposite to the first direction;
at least one thin film transistor (TFT) circuitry constructed directly on the first face; and
a PCB assembly arranged on the first face and comprising a plurality of micro LED chips electrically coupled to the at least one TFT circuitry.

2. The micro LED display of claim 1, wherein the at least one TFT circuitry is disposed to a same layer between the plurality of micro LED chips.

3. The micro LED display of claim 1, wherein the second face comprises a second circuitry.

4. The micro LED display of claim 3, wherein the PCB comprises:
at least one via; and
at least one conductive substance constructed in such a manner that the at least one via is filled with a conductive material.

5. The micro LED display of claim 4, wherein each of the plurality of micro LED chips is electrically coupled to the second circuitry by means of the at least one conductive substance.

6. The micro LED display of claim 1, wherein the PCB has a multi-layered structure.

7. The micro LED display of claim 1, wherein a process of manufacturing the at least one TFT circuitry is performed at a temperature less than or equal to approximately 300° C.

8. The micro LED display of claim 1, wherein the at least one TFT circuitry is disposed between pixels constructed of red green blue (RGB) micro LED chips.

9. The micro LED display of claim 8, wherein the pixels are disposed in a one-to-one manner to the at least one TFT circuitry.

10. The micro LED display of claim 1, wherein the at least one TFT circuitry is disposed equidistantly on the first face.

11. A printed circuit board (PCB) assembly of a micro light emitting diode (LED) display, the PCB assembly comprising:
a PCB comprising a first face disposed in a first direction and a second face disposed in a second direction opposite to the first direction;
at least one thin film transistor (TFT) circuitry constructed directly on the first face; and
a plurality of pixels arranged on the first face and electrically coupled to the at least one TFT circuitry.

12. The PCB assembly of claim 11, wherein the pixels are disposed in a one-to-one manner to the at least one TFT circuitry.

13. The PCB assembly of claim 11, wherein the at least one TFT circuitry is disposed equidistantly between the respective pixels.

14. The PCB assembly of claim 11, wherein the PCB comprises:
at least one via; and
at least one conductive substance constructed in such a manner that the at least one via is filled with a conductive material.

15. The PCB assembly of claim 14, wherein a process of manufacturing the at least one TFT circuitry is performed at a temperature less than or equal to approximately 300° C.

16. The PCB assembly of claim 11, wherein the at least one TFT circuitry is disposed to a same layer between a plurality of micro LED chips.

17. The PCB assembly of claim 11, wherein the second face comprises a second circuitry.

18. The PCB assembly of claim 11, wherein the PCB has a multi-layered structure.
